(19) United States
(12) Patent Application Publication
(10) Pub. No.: US 2025/0054920 A1
(43) Pub. Date: Feb. 13, 2025

(54) MULTIPLE CHIP LED PACKAGES WITH COMMON ELECTRODES

(71) Applicant: CreeLED, Inc., Durham, NC (US)

(72) Inventors: Robert David Schmidt, Wake Forest, NC (US); Joseph M. Favale, JR., Cary, NC (US); Jesse Reiherzer, Raleigh, NC (US)

(21) Appl. No.: 18/512,165

(22) Filed: Nov. 17, 2023

Related U.S. Application Data
(60) Provisional application No. 63/518,219, filed on Aug. 8, 2023.

(51) Int. Cl. H01L 25/075; H01L 33/62

(52) U.S. Cl. CPC H01L 25/0753; H01L 33/62

(57) ABSTRACT

Light-emitting diode (LED) packages and more particularly multiple chip LED packages with common electrodes are disclosed. LED packages include lead frame structures with a common electrode for multiple LED chips and other corresponding electrodes separately coupled to individual ones of the LED chips. The common electrode forms an anode or a cathode connection for each of the LED chips. The common electrode includes multiple extensions or pins that separately exit the package to provide separate external electrical connections to the common electrode. The common electrode may provide increased surface area of metal within the LED package to form an improved thermal body for heat dissipation. Multiple pin extensions from the common electrode allow LED packages to maintain a same form factor to be a drop in replacement for existing packages and allow enhanced adhesion with a housing that encases the lead frame structure.

### RELATED APPLICATIONS

This application claims the benefit of provisional patent application Ser. No. 63/518,219, filed Aug. 8, 2023, the disclosure of which is hereby incorporated herein by reference in its entirety.

### FIELD OF THE DISCLOSURE

The present disclosure relates to light-emitting diode (LED) packages and more particularly to multiple chip LED packages with common electrodes.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials. Photons generated by the active region are initiated in all directions.

LED packages have been developed that can provide mechanical support, electrical connections, and encapsulation for LED emitters. Lumiphoric materials, such as phosphors, may also be arranged in close proximity to LED emitters to convert portions of light emissions to different wavelengths. Multiple chip LED packages, such as LED packages with different colored LED chips, are commonly used in LED display applications. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) packages and more particularly to multiple chip LED packages with common electrodes. LED packages may include lead frame structures with a common electrode for multiple LED chips and other corresponding electrodes separately coupled to individual ones of the LED chips. The common electrode may form an anode or a cathode connection for each of the LED chips. The common electrode may include multiple extensions or pins that separately exit the package to provide separate external electrical connections to the common electrode. The common electrode provides increased surface area of metal within the LED package to form an improved thermal body for heat dissipation. Multiple pin extensions from the common electrode may allow LED packages to maintain a same form factor and be a drop-in replacement for existing packages and may allow enhanced adhesion with the body or housing that encases the lead frame structure.

In one aspect, an LED package comprises: a first LED chip; a second LED chip; a third LED chip; a housing; a lead frame structure at least partially within the housing and electrically coupled to the first LED chip, the second LED chip, and the third LED chip, the lead frame structure comprising: a first lead electrically connected to the first LED chip, the second LED chip, and the third LED chip, the first lead comprising multiple pins that extend out of the housing; a second lead electrically connected to the first LED chip; and a third lead electrically connected to the second LED chip. In certain embodiments, the first lead forms a common anode connection for the first LED chip, the second LED chip, and the third LED chip. In certain embodiments, the first lead forms a common cathode connection for the first LED chip, the second LED chip, and the third LED chip. In certain embodiments, the first lead extends from a first edge of the housing and past a center line of the housing. In certain embodiments: a surface of the multiple pins defines a package mounting surface in a first plane; surfaces of the first lead and second lead define LED chip mounting surfaces in a second plane; and an intermediate portion of the lead frame structure extends between the first plane and the second plane.

In certain embodiments, the housing forms a recess in which the first LED chip, the second LED chip, and the third LED chip reside. The LED package may further comprise a light collector within the recess and over the first LED chip, the second LED chip, and the third LED chip, the light collector forming an aperture configured to pass light from the first LED chip, the second LED chip, and the third LED chip. The LED package may further comprise a fill material within the recess and covering portions of the light collector. In certain embodiments, the housing forms a first recess in which the first LED chip resides, a second recess in which the second LED chip resides, and a third recess in which the third LED chip resides.

In certain embodiments, the first LED chip, the second LED chip, and the third LED chip are mounted on and thermally coupled with the first lead. In certain embodiments, the first LED chip is further mounted on and thermally coupled with the second lead; the second LED chip is further mounted on and thermally coupled with the third lead; and the third LED chip is further mounted on and thermally coupled with a fourth lead of the lead frame structure. In certain embodiments, the LED package further comprises a fourth LED chip, wherein the first lead is a common electrode for the first LED chip, the second LED chip, the third LED chip, and the fourth LED chip.

In another aspect, an LED package comprises: a housing; a first LED chip; a second LED chip; a lead frame structure with a first lead, the first lead forming a common electrode for the first LED chip and the second LED chip, the first lead comprising multiple pins that extend from a same side of the housing, the multiple pins being configured to receive external electrical connections to the common electrode. In certain embodiments, the common electrode is a common anode connection for the first LED chip and the second LED chip. In certain embodiments, the common electrode is a common cathode connection for the first LED chip and the second LED chip. In certain embodiments, a surface of the multiple pins defines a package mounting surface in a first plane; a surface of the first lead defines an LED chip mounting surface in a second plane; and an intermediate portion of the lead frame structure extends between the first plane and the second plane. In certain embodiments, the housing forms a recess in which the first LED chip and the second LED chip reside. The LED package may further comprise a light collector within the recess and over the first LED chip and the second LED chip, the light collector forming an aperture configured to pass light from the first LED chip and the second LED chip. The LED package may further comprise a fill material within the recess and covering portions of the light collector. In certain embodiments, the housing forms a first recess in which the first LED chip resides and a second recess in which the second LED chip resides. The LED package may further comprise a third LED chip, wherein the first lead is the common electrode for the first LED chip, the second LED chip, and the third LED chip. In certain embodiments: the lead frame structure further comprises a second lead and a third lead; the first LED chip is flip-chip mounted between the first lead and the second lead; and the second LED chip is flip-chip mounted between the first lead and the third lead. In certain embodiments, the first LED chip and the second LED chip are mounted on and thermally coupled with the first lead.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a top view of a light-emitting diode (LED) package with multiple LED chips according to principles of the present disclosure.

FIG. 2 is a top view of an LED package that is similar to the LED package of FIG. 1 except the LED chips are connected with one or more wire bonds.

FIG. 3 is a perspective view of an LED package that is similar to the LED package of FIG. 1 and illustrates an exemplary surface mount device (SMD) structure.

FIG. 4 is a cross section of an LED package where indentations are provided in the leads along a vertical length within the housing.

FIG. 5 is a cross section of an LED package that is similar to the LED package of FIG. 4 but without the indentations of FIG. 4.

FIG. 6 is a cross section of an LED package that is similar to the LED package of FIG. 4 with a single indentation for each of the leads.

FIG. 7A is a top view of an LED package that is similar to the LED package of FIG. 1 where the lead is provided with increased surface area.

FIG. 7B is a top view of an LED package that is similar to the LED package of FIG. 7A for embodiments where the LED chips embody vertical and/or lateral structures with wire bonds.

FIG. 7C is a top view of an LED package that is similar to the LED package of FIG. 7A for embodiments where the lead includes one or more through-holes.

FIG. 7D is a top view of an LED package that is similar to the LED package of FIG. 7B for embodiments where the lead includes one or more through-holes.

FIG. 8A is a top view of an LED package that is similar to the LED package of FIG. 1 where the lead is provided with an alternative shape.

FIG. 8B is a top view of an LED package that is similar to the LED package of FIG. 8A for embodiments where the LED chips embody vertical and/or lateral structures with wire bonds.

FIG. 9A is a top view of an LED package that is similar to the LED package of FIG. 1 where the lead is provided with increased surface area along a central portion thereof.

FIG. 9B is a top view of an LED package that is similar to the LED package of FIG. 9A for embodiments where the LED chips embody vertical and/or lateral structures with wire bonds.

FIG. 9C is a top view of an LED package that is similar to the LED package of FIG. 9B except the position of the LED chips are reversed to provide a linear arrangement.

FIG. 10A is a top view of an LED package that is similar to the LED package of FIG. 9A where the lead is provided with increased surface area along a central portion thereof with a different shape than FIG. 9A.

FIG. 10B is a top view of an LED package that is similar to the LED package of FIG. 10A for embodiments where the LED chips embody vertical and/or lateral structures with wire bonds.

FIG. 10C is a top view of an LED package that is similar to the LED package of FIG. 10A for embodiments where the lead includes at least one through-hole.

FIG. 10D is a top view of an LED package that is similar to the LED package of FIG. 10B for embodiments where the lead includes at least one through-hole.

FIG. 11A is a top view of an LED package that is similar to the LED package of FIG. 1 where pins of the lead are arranged on opposing sides of the housing.

FIG. 11B is a top view of an LED package that is similar to the LED package of FIG. 11A for embodiments where the LED chips embody vertical and/or lateral structures with wire bonds.

FIG. 12A is a top view of an LED package that is similar to the LED package of FIG. 11A where the shapes of the leads are modified to position the LED chips closer to one another.

FIG. 12B is a top view of an LED package that is similar to the LED package of FIG. 12A for embodiments where the LED chips embody vertical and/or lateral structures with wire bonds.

FIG. 13A is a top view of an LED package that is similar to the LED package of FIG. 11A with a different arrangement of the leads relative to one another.

FIG. 13C is a top view of an LED package that is similar to the LED package of FIG. 13A for embodiments where the lead includes at least one through-hole.

FIG. 13D is a top view of an LED package that is similar to the LED package of FIG. 13B for embodiments where the lead includes at least one through-hole.

FIG. 14A is a top view of an LED package that is similar to the LED package of FIG. 11A with a different arrangement of the leads relative to one another.

FIG. 14B is a top view of an LED package that is similar to the LED package of FIG. 14A for embodiments where the LED chips embody vertical and/or lateral structures with wire bonds.

FIG. 14C is a top view of an LED package that is similar to the LED package of FIG. 14A for embodiments where the lead includes at least one through-hole.

FIG. 14D is a top view of an LED package that is similar to the LED package of FIG. 14B for embodiments where the lead includes at least one through-hole.

FIG. 15A is a top view of an LED package that is similar to the LED package of FIG. 14A with a different arrangement of the leads relative to one another.

FIG. 15B is a top view of an LED package that is similar to the LED package of FIG. 15A for embodiments where the LED chips embody vertical and/or lateral structures with wire bonds.

FIG. 15C is a top view of an LED package that is similar to the LED package of FIG. 15A for embodiments where the lead includes at least one through-hole.

FIG. 15D is a top view of an LED package that is similar to the LED package of FIG. 15B for embodiments where the lead includes at least one through-hole.

FIG. 16A is a top view of an LED package that is similar to the LED package of FIG. 14A with a different arrangement of the leads relative to one another.

FIG. 16B is a top view of an LED package that is similar to the LED package of FIG. 16A for embodiments where the LED chips embody vertical and/or lateral structures with wire bonds.

FIG. 17A is a top view of an LED package that is similar to the LED package of FIG. 1 for embodiments where the lead is a common electrode for at least four LED chips.

FIG. 17B is a top view of an LED package that is similar to the LED package of FIG. 17A for embodiments where the LED chips embody vertical and/or lateral structures with wire bonds.

FIG. 18A is a top view of an LED package that is similar to the LED package of FIG. 17A for embodiments where the lead is a common electrode for at least four LED chips and extends between opposing corners of the housing.

FIG. 18B is a top view of an LED package that is similar to the LED package of FIG. 18A for embodiments where the LED chips embody vertical and/or lateral structures with wire bonds.

FIG. 19A is a top view of an LED package that is similar to the LED package of FIG. 17A for embodiments where the lead is a common electrode for at least four LED chips and extends from one corner of the housing to another corner that is on a same side of the housing.

FIG. 19B is a top view of an LED package that is similar to the LED package of FIG. 19A for embodiments where the LED chips embody vertical and/or lateral structures with wire bonds.

FIG. 20A is a top view of an LED package that is similar to the LED package of FIG. 19A for embodiments where the lead is a common electrode for at least four LED chips and the pins are adjacent to one another on a same side of the housing.

FIG. 20B is a top view of an LED package that is similar to the LED package of FIG. 20A for embodiments where the LED chips embody vertical and/or lateral structures with wire bonds.

FIG. 20C is a top view of an LED package that is similar to the LED package of FIG. 20A for embodiments where the lead includes at least one through-hole.

FIG. 20D is a top view of an LED package that is similar to the LED package of FIG. 20B for embodiments where the lead includes at least one through-hole.

FIG. 21A is a top view of an LED package that is similar to the LED package of FIG. 13A with the addition of a light collector.

FIG. 21B is a cross-section of the LED package of FIG. 21A taken along the sectional line 21B-21B of FIG. 21A.

FIG. 22A is a top view of an LED package with multiple cavities or recesses for the multiple LED chips and a common electrode according to principles of the present disclosure.

FIG. 22B is a top view of an LED package that is similar to the LED package of FIG. 22A except the leads do not have the bump out portion as illustrated in FIG. 21A.

FIG. 22C is a top view of a lead frame structure that may be implemented in the LED package of FIG. 22A.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) packages and more particularly to multiple chip LED packages with common electrodes. LED packages may include lead frame structures with a common electrode for multiple LED chips and other corresponding electrodes separately coupled to individual ones of the LED chips. The common electrode may form an anode or a cathode connection for each of the LED chips. The common electrode may include multiple extensions or pins that separately exit the package to provide separate external electrical connections to the common electrode. The common electrode provides increased surface area of metal within the LED package to form an improved thermal body for heat dissipation. Multiple pin extensions from the common electrode may allow LED packages to maintain a same form factor and be a drop-in replacement for existing packages and may allow enhanced adhesion with the body or housing that encases the lead frame structure.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group Ill nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group Ill nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds.

The active LED structure may be grown on a growth substrate that can include many materials, such as sapphire, SiC, silicon, aluminum nitride (AlN), and GaN. Sapphire is a common substrate for Group Ill nitrides and has certain advantages, including being lower cost, having established manufacturing processes, and having good light-transmissive optical properties.

Different embodiments of the active LED structure can emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount or lead frame of an LED package such that the anode and cathode connections are on a face of the LED chip that is opposite the submount or lead frame. In this configuration, wire bonds may be used to provide electrical connections with the anode and cathode connections. In other embodiments, a lateral geometry LED chip may be flip-chip mounted on a surface of a submount or lead frame of an LED package such that the anode and cathode connections are on a face of the active LED structure that is adjacent to the submount or lead frame. In the context of lead frames, leads of a lead frame structure are provided as electrical connections to the anode and cathode connections of one or more LED chips. In a flip-chip configuration, the active LED structure is configured between the substrate of the LED chip and the lead frame structure of the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. Light-altering materials may be arranged within LED packages to reflect or otherwise redirect light from the one or more LED chips in a desired emission direction or pattern. In certain aspects, an LED package may include a support member, such as a submount or a lead frame.

In certain embodiments, aspects of the present disclosure relate LED packages with lead frame structures that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The body may be formed on the lead frame structure before singulation so that the individual lead frame portions may be electrically isolated from one another and mechanically supported by the body within an individual LED package. The body may form a cup or a recess in which one or more LED chips may be mounted to the lead frame at a floor of the recess. Portions of the lead frame structure may extend from the recess and through the body to protrude or be accessible outside of the body to provide external electrical connections. An encapsulant material, such as silicone or epoxy, may fill the recess to encapsulate the one or more LED chips.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

Multiple chip LED packages typically include two or more LED chips housed and electrically connected within a common package. Exemplary multiple chip packages include those with red, blue, and green emitting LED chips. Additional exemplary packages may further include a white LED chip that is a blue or green LED chip with a corresponding lumiphoric material, such as phosphor. In still further applications, the principles disclosed are equally applicable to multiple LED chips of a same emission color within a common package. For lead frame structures, it is common to have separate pairs of leads for each LED chip. For example, a three chip LED package may have six total leads that couple with the LED chips and extend out of the LED package for receiving external electrical connections. In this regard, a three LED chip package with a lead frame structure may be referred to as a six pin LED package. In a similar manner, a two chip LED package may be referred to as a four pin LED package and a four chip LED package may bay be referred to as an eight pin LED package. Such lead frame-based LED packages are sometimes referred to as surface mount devices (SMDs) as the portions of the leads that exit the package (e.g., the pins) are electrically coupled to external connections when the package is mounted to another surface, such as a printed circuit board or the like.

According to aspects of the present disclosure, multiple chip LED packages are described that reduce a plurality of cathode leads or a plurality of anode leads to a single common electrode. The single common electrode may be formed by a single lead or pad of a lead frames structure. For example, in a three chip LED package, rather than having six total leads of a lead frame, one of the anode or cathode connection is combined for all chips. Accordingly, the three chip LED package may include four total leads while still maintaining individual addressability for each LED chip. While a single common electrode lead for the anode or cathode connections is provided, the single common electrode lead may still include multiple extensions that exit the package so that a three chip LED package may still have six total pins for electrical connections. In such embodiments, three of the six total pins are electrically coupled together within the package to form the common electrode for the anode or cathode connection.

Aspects of the present disclosure may provide numerous advantages over conventional packages. For example, such structures may be advantageous for the use of flip-chip style LED chips in SMD packages where the LED chips are thermally and electrically coupled to the package without the need for bonding wires. Additionally, the common electrode provides increased surface area of metal within the LED package to form an improved thermal body for heat dissipation. In certain embodiments, maintaining multiple pin extensions from the common electrode may allow LED packages to maintain a same form factor and be a drop-in replacement for existing packages. In still further embodiments, the multiple pin extensions may allow enhanced adhesion with the body or housing that encases the lead frame structure.

In certain embodiments, the common electrode with multiple pins may more readily allow the use of flip-chip LED chips. In flip-chip bonding, it is advantageous to have a level or planar surface for mounting. The common electrode allows enhanced alignment by providing a common mounting surface for the anode or cathode of the multiple flip-chips. In such embodiments, enhanced reliability may be realized by reducing or eliminating the presence of wire bonding, thereby avoiding possible known failure mechanisms associated with wire bonds, and enhanced thermal escape for heat dissipation may extend the longevity of the LED packages. In certain embodiments, improved light output performance may be realized by flip-chip arrangements that reduce and/or eliminate absorbing materials (e.g., excess gold bonding wire) that would otherwise be present in the light escape path. Such lead frame structures may also more readily promote alternative LED chip layouts beyond linear for better or more desirable pairing to an integrated optical collector of the package for enhanced light mixing and uniformity of package emissions. For example, LED chip layouts may more readily allow avoiding placement of an LED chip at a center point of the package, such as a triangular or off-center orientation for multiple LED chips to more evenly distribute light to the optical collector. While aspects of the present disclosure are applicable to flip-chip LED chips, the principles disclosed may also be applicable for LED chips that employ bond wire connections.

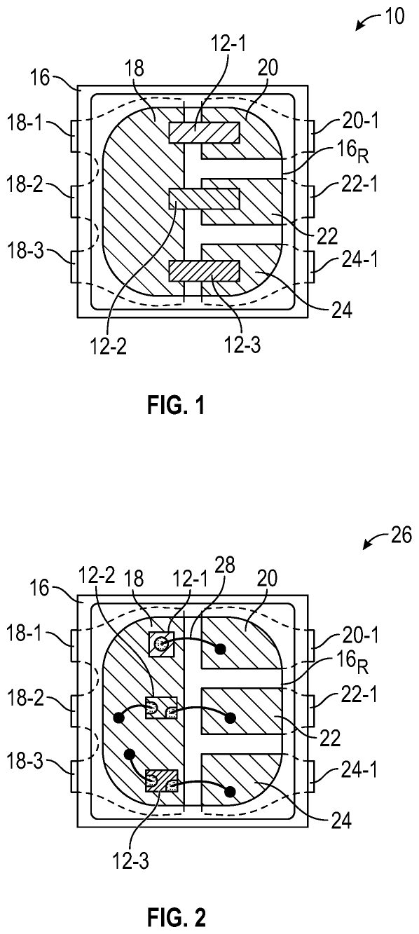

FIG. 1 is a top view of an LED package 10 with multiple LED chips 12-1 to 12-3 according to principles of the present disclosure. The LED chips 12-1 to 12-3 may be configured to all emit a same emission color, or the LED chips 12-1 to 12-3 may be configured to emit different emission colors, such as red, green, and blue wavelengths. The LED package 10 is a lead frame package that includes a lead frame structure collectively formed by leads 18, 20, 22, 24 within a housing 16. The LED chips 12-1 to 12-3 are within a recess 16R of the housing 16 and are mounted and/or electrically coupled to portions of the leads 18, 20, 22, 24 that are exposed at a bottom of the recess 16R. In FIG. 1, each LED chip 12-1 to 12-3 is a flip-chip LED structure that is electrically coupled to the common lead 18. The other leads 20, 22, 24 provide the separate electrical connections to corresponding ones of the LED chips 12-1 to 12-3. In this manner, the lead 18 may form a common electrode (e.g., common anode or cathode) for each of the LED chips 12-1 to 12-3 while the leads 20, 22, 24 provide the others of anode or cathode connections in a separated manner. As illustrated, portions of the lead 18 extend out of the housing 16 to form multiple pins 18-1 to 18-3. In a similar manner, each of the leads 20, 22, 24 form corresponding pins 20-1, 22-1, 24-1 that also extend out of the housing 16. As such, the LED package 10 includes multiple LED chips 12-1 to 12-3 with a number of leads 18, 20, 22, 24 that is less than two times the number of LED chips 12-1 to 12-3 while also having a number of pins 18-1 to 18-3, 20-1, 22-1, 24-1 that is two times the number of LED chips 12-1 to 12-3. For illustrative purposes, portions of the leads 18, 20, 22, 24 that are within the housing 16 are illustrated with dashed lines.

FIG. 2 is a top view of an LED package 26 that is similar to the LED package 10 of FIG. 1 except the LED chips 12-1 to 12-3 are connected with one or more wire bonds 28. In this regard, the lead frame structure formed by the leads 18, 20, 22, 24 may also be applicable when any of the LED chips 12-1 to 12-3 do not have flip-chip structures. By way of example, the LED chip 12-1 is illustrated with a single wire bond 26, thereby embodying a vertical chip structure. The LED chips 12-2, 12-3 are illustrated with two wire bonds 28, thereby embodying lateral chip structures. In certain embodiments, each of the LED chips 12-1 to 12-3 is mounted to the same lead 18, and wire bonds 28 provide connections to corresponding ones of the leads 20, 22, 24.

FIGS. 1 and 2 are provided to illustrate that any of the principles of the present disclosure and embodiments in later figures may include multiple LED chips with flip-chip structures, vertical structures, lateral structures, and any combinations thereof within a same package.

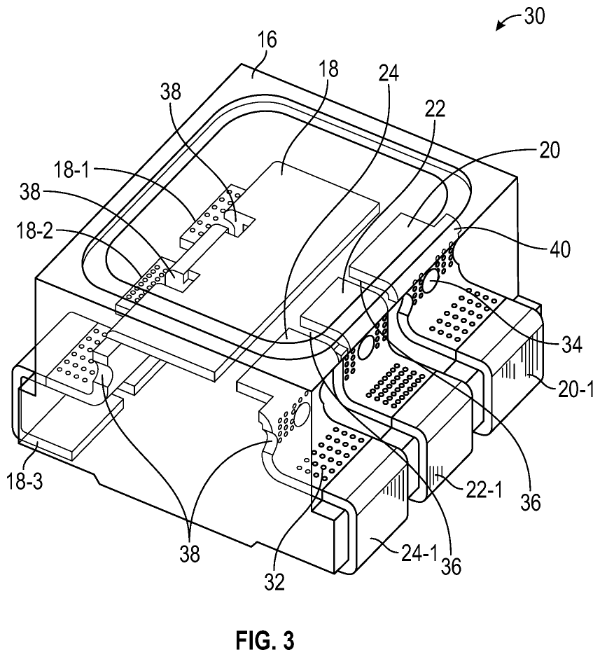

FIG. 3 is a perspective view of an LED package 30 that is similar to the LED package 10 of FIG. 1 and illustrates an exemplary SMD structure. For illustrative purposes, the housing 16 is shown as transparent and the LED chips 12-1 to 12-3 of FIG. 1 are omitted. As illustrated, the lead 18 includes multiple pins 18-1 to 18-3 that extend out of the housing 16 and wrap around bottom portions of the housing 16. In a similar manner, the pins 20-1, 22-1, 24-1 of the leads 20, 22, 24 also extend out of the housing 16 and wrap around bottom portions of housing 16 from an opposing side. In certain embodiments, the leads 18, 20, 22, 24 have multiple bends within the housing 16, such as a so-called S-shape to promote improved adhesion with the housing 16. The lead frame structure may also include a variety of other possible features to enhance casing/lead frame adhesion, such as stepped portions (e.g., portions of the S-shape or S-leg), spot punches 32, through-holes 34, metal gaps 36, indentations 38, and tabs 40. Such features provide improvements to the structural integrity of the LED package 30 and make it more resistant to water (and other contaminants or environmental ingress). Additionally, the adhesion reliability between the housing 16 and the lead frame structure is enhanced. In this manner, these shapes provide varying amounts of surface area for the lead frame structure, which the material of the housing 16 may encompass to improve structural integrity.

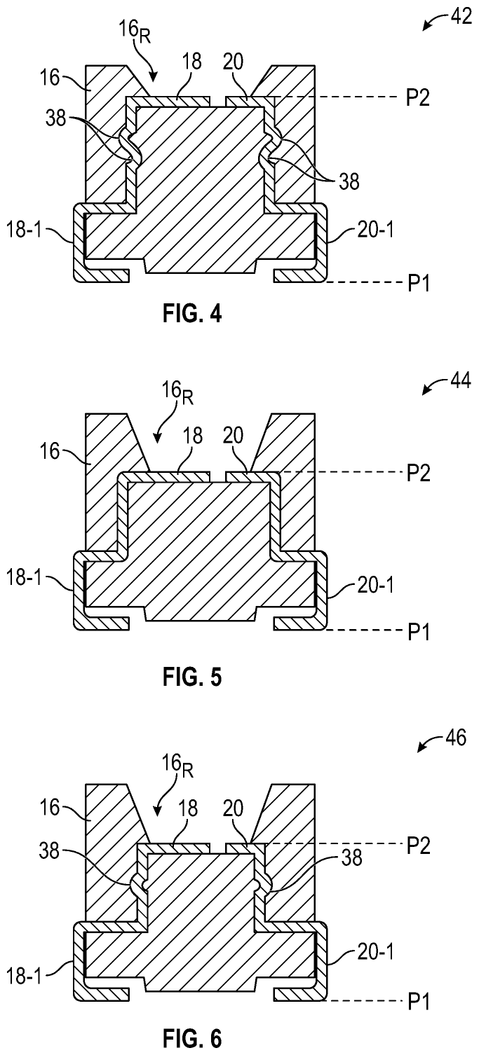

FIGS. 4-6 depict possible embodiments for shapes of lead frame structures similar to those in the LED package 30 of FIG. 3. FIGS. 4-6 provide cross-sectional views that include the leads 18, 20 and corresponding pins 18-1, 20-1 as illustrated in FIG. 3.

FIG. 4 is a cross section of an LED package 42 where indentations 38 are provided in the leads 18, 20 along a vertical length within the housing 16. A package mounting surface may be defined along a first plane P1 at a bottom surface of the pins 18-1, 20-1, and an LED chip mounting surface may be defined along a second plane P2 at a top surface of the leads 18, 20 within the recess 16R. Other portions of the leads 18, 20 (and remainder of the lead frame structure) may form intermediate portions that extend between the first plane P1 and the second plane P2. Accordingly, the indentations 38 are provided on portions of the leads 18, 20 that are between the first plane P1 and the second plane P2. The indentations 38 increase the available surface area for the improved bonding and adhesion with the housing 16.

FIG. 5 is a cross section of an LED package 44 that is similar to the LED package 42 of FIG. 4 but without the indentations 38 of FIG. 4. As illustrated, this configuration may allow for a smaller length of the lead frame between the first plane P1 and the second plane P2, which may allow the depth of the recess 16R to be increased relative to FIG. 4.

FIG. 6 is a cross section of an LED package 46 that is similar to the LED package 42 of FIG. 4 with a single indentation 38 for each of the leads 18, 20. According to principles of the present disclosure, lead frame structures may have any number of features, such as the indentations 38, for promoting improved adhesion and reduced environmental ingress. As described above, the lead 18 may form a common electrode for multiple LED chips. By forming multiple pins 18-1 to 18-3 that extend from the same lead 18, additional surface area is provided for the presence of indentations 38 and/or the stepped portions, punches 32, through-holes 34, metal gaps 36, and/or tabs 40 as illustrated in FIG. 3.

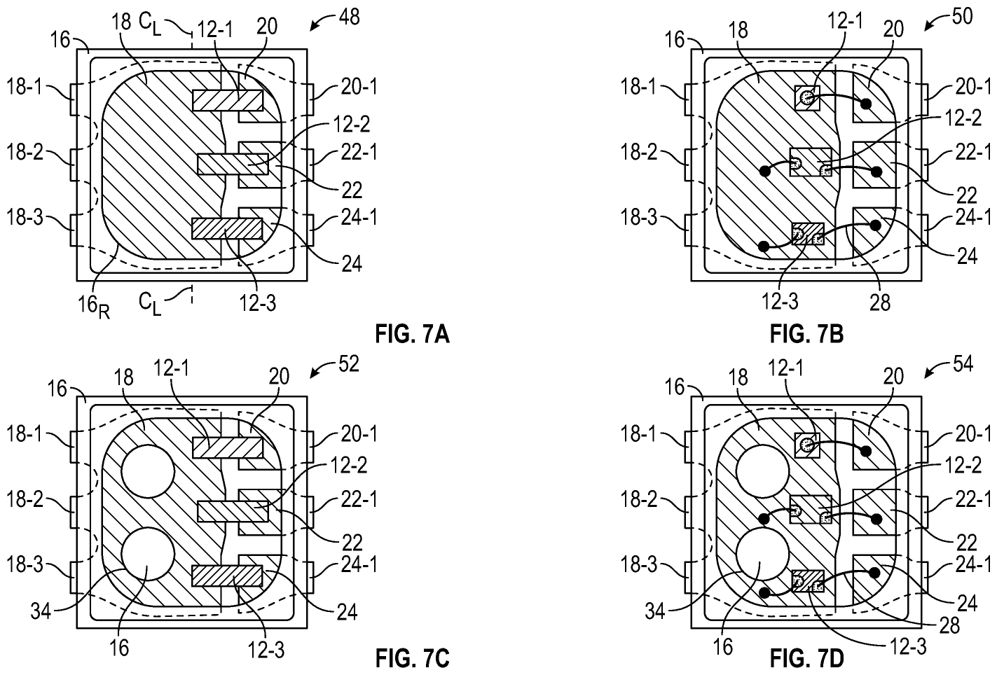

FIGS. 7A to 20D illustrate various configurations of LED packages that are similar to the LED package 10 of FIG. 1 or the LED package 26 of FIG. 2. FIGS. 7A to 20D illustrate advantages in layouts of lead frame structures when implementing the common electrode (e.g., common anode or common cathode) for the lead 18 according to principles of the present disclosure.

FIG. 7A is a top view of an LED package 48 that is similar to the LED package 10 of FIG. 1 where the lead 18 is provided with increased surface area. In FIG. 7A, the LED chips 12-1 to 12-3 have flip-chip structures. As illustrated, the lead 18 extends past a center line CL of the housing 16 and/or the recess 16R, the center line CL being defined between opposing sides of the housing 16 where the pin 18-1 and the leads 20, 22, 24 respectively exit the housing 16. The increased surface area may provide increased thermal spreading for the LED chips 12-1 to 12-3. Additionally, such a structure may position the LED chips 12-1 to 12-3 off center for certain emission applications. As illustrated, the lead 18 may have a tab or lateral protrusion proximate the LED chip 12-2 for mounting and for increased surface area along a center of the housing 16. FIG. 7B is a top view of an LED package 50 that is similar to the LED package 48 of FIG. 7A for embodiments where the LED chips 12-1 to 12-3 embody vertical and/or lateral structures with wire bonds 28. FIG. 7C is a top view of an LED package 52 that is similar to the LED package 48 of FIG. 7A for embodiments where the lead 18 includes one or more through-holes 34. The increased surface area of the lead 18 may allow positioning of the through-holes 34 so that portions of the housing 16 at least partially fill the through-holes 34 for improved adhesion. FIG. 7D is a top view of an LED package 54 that is similar to the LED package 50 of FIG. 7B for embodiments where the lead 18 includes the one or more through-holes 34.

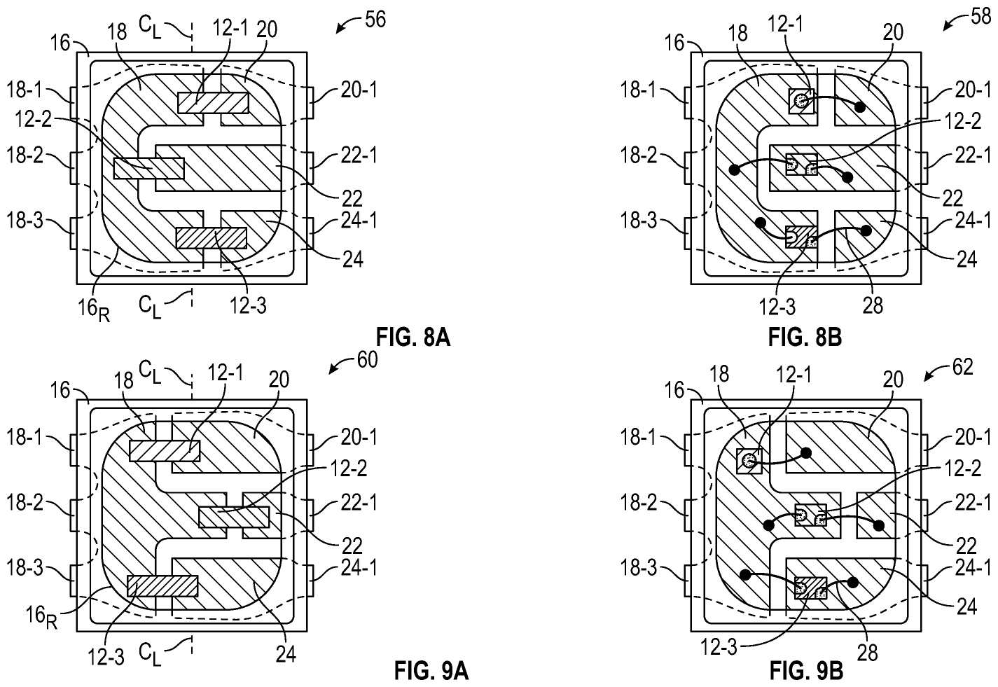

FIG. 8A is a top view of an LED package 56 that is similar to the LED package 10 of FIG. 1 where the lead 18 is provided with an alternative shape. For example, portions of the lead 18 extend past the center line CL for the LED chips 12-1 and 12-3. In a similar manner, the lead 22 also extends past the center line CL from the opposite side of the housing 16 for the LED chip 12-2. In this manner, the leads 18, 20, 24 may form an interdigitated arrangement. As illustrated, this provides a layout (e.g., triangular) for the LED chips 12-1 to 12-3 that avoids having any of the LED chips 12-1 to 12-3 positioned at a center point of the recess 16R. This layout may be advantageous for applications that employ a light collector as will be later described in greater detail. FIG. 8B is a top view of an LED package 58 that is similar to the LED package 56 of FIG. 8A for embodiments where the LED chips 12-1 to 12-3 embody vertical and/or lateral structures with wire bonds 28. In FIG. 8B, positions of the LED chips 12-1 to 12-3 are not necessarily the same as in FIG. 8A, illustrating the flexibility of the design for different embodiments. In particular, the LED chips 12-1 to 12-3 in FIG. 8B are provided in a linear arrangement.

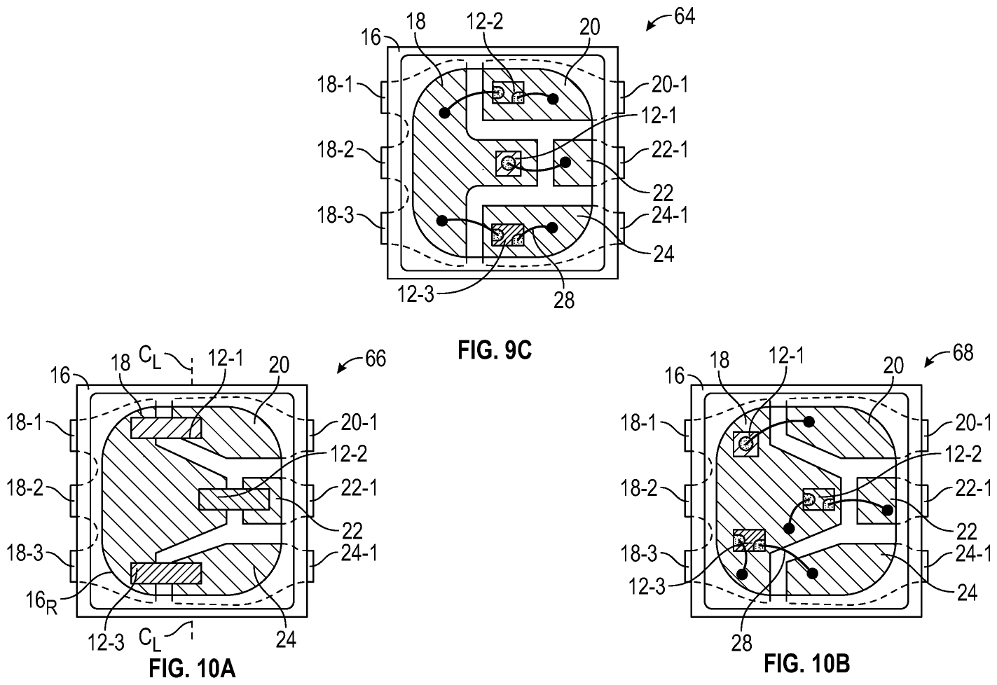

FIG. 9A is a top view of an LED package 60 that is similar to the LED package 10 of FIG. 1 where the lead 18 is provided with increased surface area along a central portion thereof. For example, the lead 18 extends past the center line CL for the LED chip 12-2. In a similar manner, the leads 20 and 24 also extend past the center line CL from the opposite side of the housing 16 as the lead 18. In this manner, the leads 18, 20, 24 may form an interdigitated arrangement. As illustrated, this provides a layout (e.g., triangular) for the LED chips 12-1 to 12-3 that avoids having any of the LED chips 12-1 to 12-3 positioned at a center point of the recess 16R. FIG. 9B is a top view of an LED package 62 that is similar to the LED package 60 of FIG. 9A for embodiments where the LED chips 12-1 to 12-3 embody vertical and/or lateral structures with wire bonds 28. FIG. 9C is a top view of an LED package 64 that is similar to the LED package 62 of FIG. 9B except the position of the LED chips 12-1 and 12-2 are reversed to provide a linear arrangement. As illustrated, the LED chip 12-1 may embody a vertical structure with a single wire bond 38.

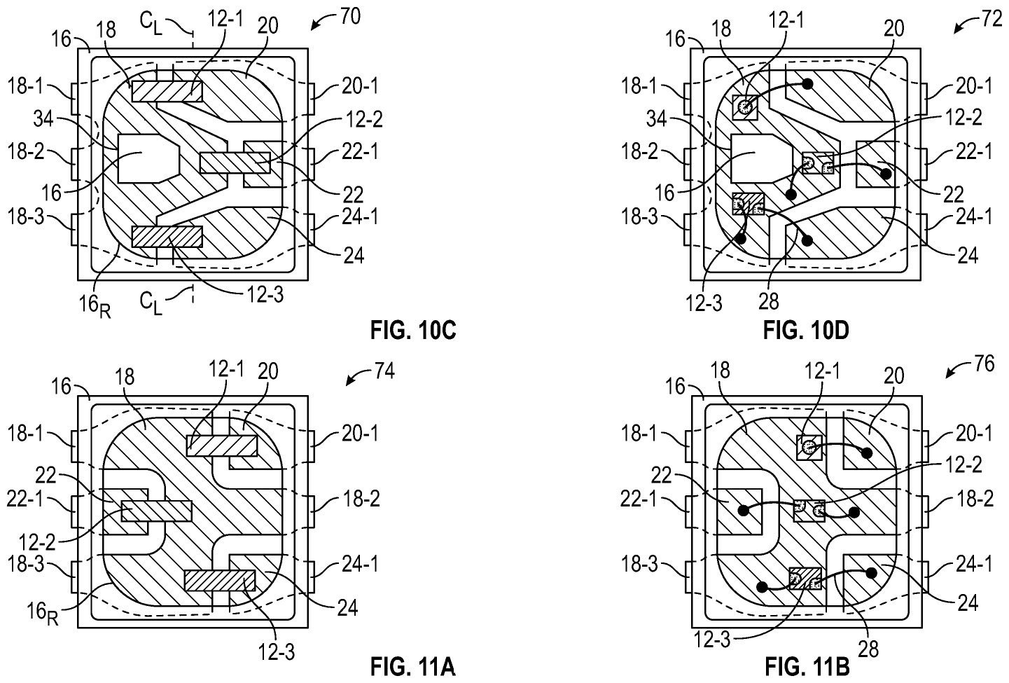

FIG. 10A is a top view of an LED package 66 that is similar to the LED package 60 of FIG. 9A where the lead 18 is provided with increased surface area along a central portion thereof with a different shape than FIG. 9A. In FIG. 10A, a portion of the lead 18 extends past the center line CL for the LED chip 12-2, and this portion forms angled edges to provide increased surface area relative to FIG. 9A. FIG. 10B is a top view of an LED package 68 that is similar to the LED package 66 of FIG. 10A for embodiments where the LED chips 12-1 to 12-3 embody vertical and/or lateral structures with wire bonds 28. FIG. 10C is a top view of an LED package 70 that is similar to the LED package 66 of FIG. 10A for embodiments where the lead 18 includes at least one through-hole 34. The increased surface area of the lead 18 may allow positioning of the through-hole 34 so that portions of the housing 16 at least partially fill the through-hole 34 for improved adhesion. Additionally, the portion of the housing 16 within the through-hole 34 may form a surface within the recess 16R with increased reflectivity since, in certain embodiments, the material of the housing 16 may be more reflective to light from the LED chips 12-1 to 12-3 than surfaces of the lead 18. FIG. 10D is a top view of an LED package 72 that is similar to the LED package 68 of FIG. 10B for embodiments where the lead 18 includes at least one through-hole 34.

FIG. 11A is a top view of an LED package 74 that is similar to the LED package 10 of FIG. 1 where pins 18-1 to 18-3 of the lead 18 are arranged on opposing sides of the housing 16. As illustrated, the lead 18 may continuously extend from one side of the housing 16 to the other. Accordingly, the pins 18-1, 18-3 exit the housing 16 on one side while the pin 18-2 exits on the opposite side. Such an arrangement may also provide the layout (e.g., triangular) for the LED chips 12-1 to 12-3 that avoids having any of the LED chips 12-1 to 12-3 positioned at a center point of the recess 16R. FIG. 11B is a top view of an LED package 76 that is similar to the LED package 74 of FIG. 11A for embodiments where the LED chips 12-1 to 12-3 embody vertical and/or lateral structures with wire bonds 28. As illustrated, the LED chips 12-1 to 12-3 are provided in a linear arrangement along the lead 18.

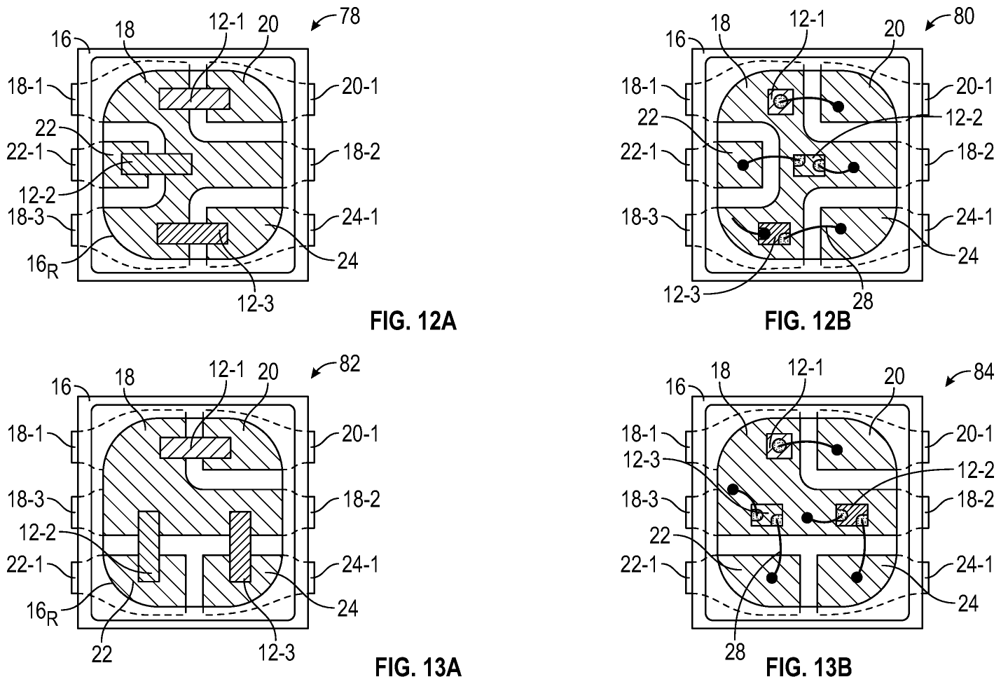

FIG. 12A is a top view of an LED package 78 that is similar to the LED package 74 of FIG. 11A where the shapes of the leads 18, 22, 24 are modified to position the LED chips 12-1 to 12-3 closer to one another. As illustrated, the LED chips 12-1 to 12-3 may still have a triangular layout. FIG. 12B is a top view of an LED package 80 that is similar to the LED package 78 of FIG. 12A for embodiments where the LED chips 12-1 to 12-3 embody vertical and/or lateral structures with wire bonds 28.

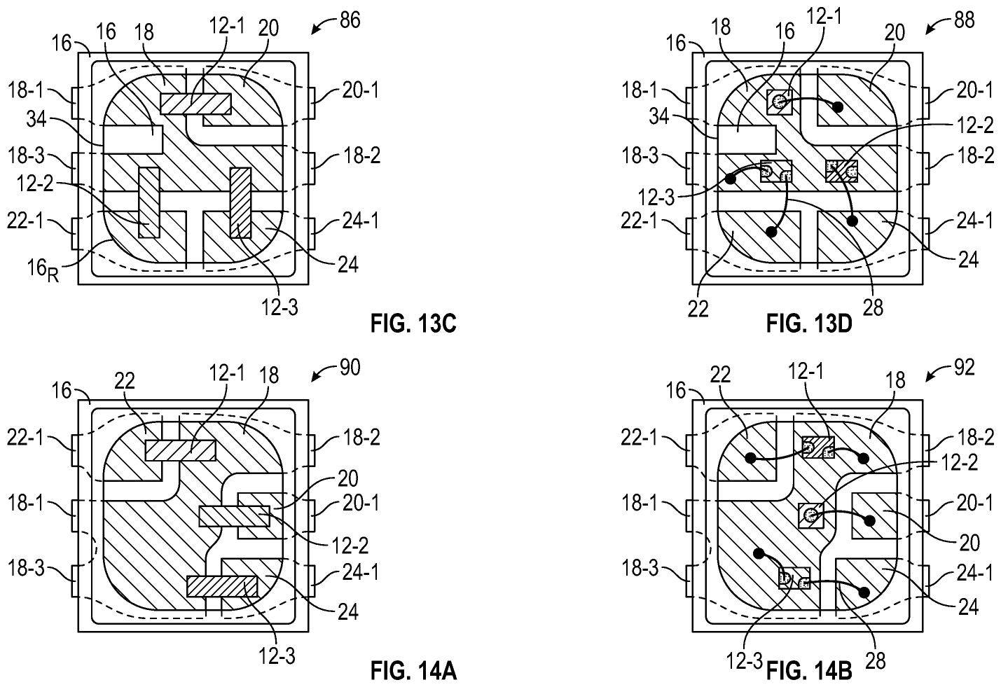

FIG. 13A is a top view of an LED package 82 that is similar to the LED package 74 of FIG. 11A with a different arrangement of the lead 18 and the leads 22, 24 relative to one another. In FIG. 13A, the lead 18 still extends from one side of the housing 16 to the other such that the pins 18-1, 18-3 are positioned on an opposite side of the housing 16 as the pin 18-2. As illustrated, the pins 18-1, 18-3 are positioned adjacent to one another on one side of the housing 16 such that the pin 18-3 is between the pin 22-1 and the pin 18-1. Such an arrangement is well suited for positioning the LED chips 12-1 to 12-3 with flip-chip structures in a layout (e.g., triangular) that avoids the center of the recess 16R. Furthermore, the arrangement of gaps between the lead 18 and the leads 20, 22, 24 allows adjustments to the positioning of the LED chips 12-1 to 12-3 closer or farther away from the center of the recess 16R. FIG. 13B is a top view of an LED package 84 that is similar to the LED package 82 of FIG. 13A for embodiments where the LED chips 12-1 to 12-3 embody vertical and/or lateral structures with wire bonds 28.

FIG. 13C is a top view of an LED package 86 that is similar to the LED package 82 of FIG. 13A for embodiments where the lead 18 includes at least one through-hole 34. As previously described, the increased surface area of the lead 18 may allow positioning of the through-hole 34 so that portions of the housing 16 at least partially fill the through-hole 34 for improved adhesion. FIG. 13D is a top view of an LED package 88 that is similar to the LED package 84 of FIG. 13B for embodiments where the lead 18 includes at least one through-hole 34.

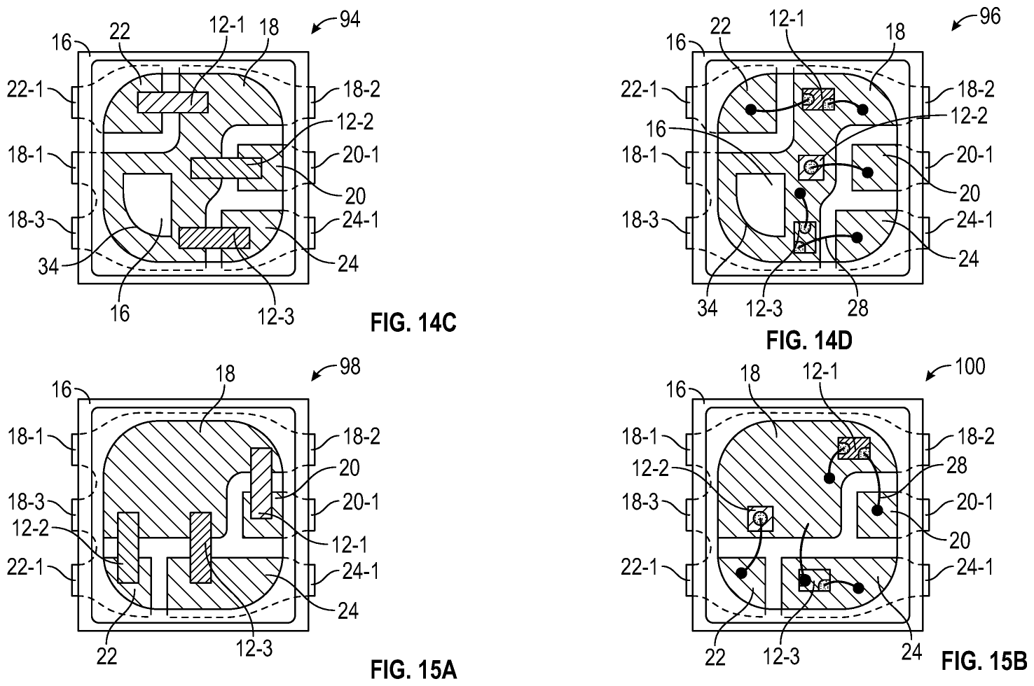

FIG. 14A is a top view of an LED package 90 that is similar to the LED package 74 of FIG. 11A with a different arrangement of the lead 18 and the leads 22, 24 relative to one another. In FIG. 14A, the lead 18 still extends from one side of the housing 16 to the other such that the pins 18-1, 18-3 are positioned on an opposite side of the housing 16 as the pin 18-2. As illustrated, the pins 18-1, 18-3 are positioned adjacent to one another on one side of the housing 16 and the pin 18-1 is between the pin 20-1 and the pin 24-1. In comparison to FIG. 11A, the positions of the pins 22-1 and 18-1 are swapped. FIG. 14B is a top view of an LED package 92 that is similar to the LED package 90 of FIG. 14A for embodiments where the LED chips 12-1 to 12-3 embody vertical and/or lateral structures with wire bonds 28. FIG. 14C is a top view of an LED package 94 that is similar to the LED package 90 of FIG. 14A for embodiments where the lead 18 includes at least one through-hole 34. FIG. 14D is a top view of an LED package 96 that is similar to the LED package 92 of FIG. 14B for embodiments where the lead 18 includes at least one through-hole 34.

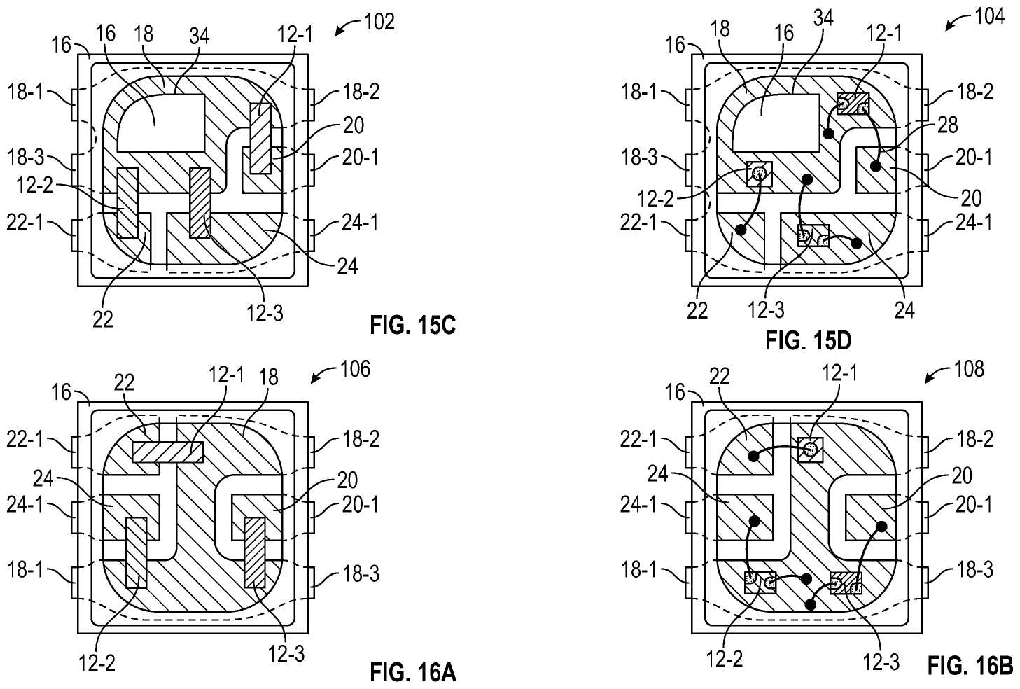

FIG. 15A is a top view of an LED package 98 that is similar to the LED package 90 of FIG. 14A with a different arrangement of the lead 18 and the leads 22, 24 relative to one another. In FIG. 15A, the lead 18 still extends from one side of the housing 16 to the other such that the pins 18-1, 18-3 are positioned on an opposite side of the housing 16 as the pin 18-2. As illustrated, the pins 18-1, 18-3 are positioned adjacent to one another on one side of the housing 16 such that the pin 18-3 is between the pin 22-1 and the pin 18-1. FIG. 15B is a top view of an LED package 100 that is similar to the LED package 98 of FIG. 15A for embodiments where the LED chips 12-1 to 12-3 embody vertical and/or lateral structures with wire bonds 28. FIG. 15C is a top view of an LED package 102 that is similar to the LED package 98 of FIG. 15A for embodiments where the lead 18 includes at least one through-hole 34. FIG. 15D is a top view of an LED package 104 that is similar to the LED package 100 of FIG. 15B for embodiments where the lead 18 includes at least one through-hole 34.

FIG. 16A is a top view of an LED package 106 that is similar to the LED package 90 of FIG. 14A with a different arrangement of the lead 18 and the leads 22, 24 relative to one another. In FIG. 16A, the lead 18 still extends from one side of the housing 16 to the other such that the pins 18-2, 18-3 are positioned on an opposite side of the housing 16 as the pin 18-1. On one side of the housing 16, the pin 24-1 is between the pins 22-1 and 18-1, while on the other side of the housing 16, the pin 20-1 is between the pins 18-2 and 18-3. Such an arrangement also provides a layout (e.g., triangular) where the LED chips 12-1 to 12-3 are positioned offset from center. FIG. 16B is a top view of an LED package 108 that is similar to the LED package 106 of FIG. 16A for embodiments where the LED chips 12-1 to 12-3 embody vertical and/or lateral structures with wire bonds 28.

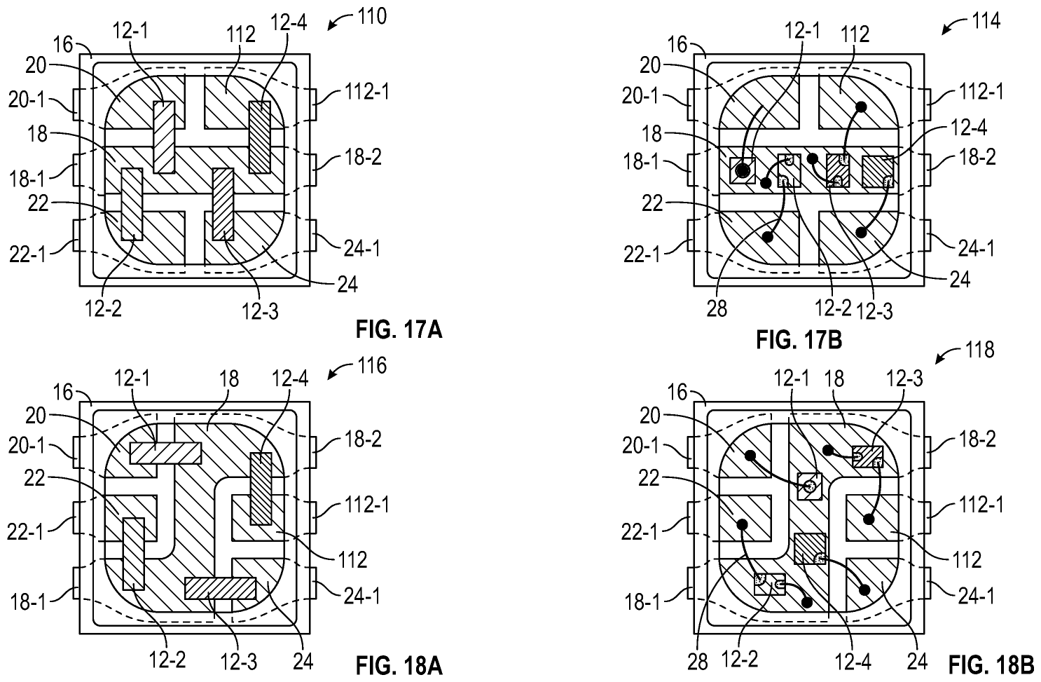

FIG. 17A is a top view of an LED package 110 that is similar to the LED package 10 of FIG. 1 for embodiments where the lead 18 is a common electrode for at least four LED chips 12-1 to 12-4. By way of example, the LED chips 12-1 to 12-4 may be configured to respectively provide red, green, blue, and white emissions, where the white emissions are provided by a blue chip with a corresponding lumiphoric material. In certain embodiments, the lead 18 may continuously extend between opposing sides of the housing 16 and the pins 18-1, 18-2 may be formed on the opposing sides of the housing 16. An additional lead 112 and corresponding pin 112-1 are provided to provide corresponding electrical connections for the fourth LED chip 12-4. As illustrated, each of the other leads 20, 22, 24, 112 forms separate electrodes for corresponding ones of the LED chips 12-1 to 12-4. In FIG. 17A, the leads 20, 22, 24, 112 are positioned at four corners of the housing 16 with the common lead 18 extending therebetween along a center portion of the housing 16. FIG. 17B is a top view of an LED package 114 that is similar to the LED package 110 of FIG. 17A for embodiments where the LED chips 12-1 to 12-4 embody vertical and/or lateral structures with wire bonds 28.

FIG. 18A is a top view of an LED package 116 that is similar to the LED package 110 of FIG. 17A for embodiments where the lead 18 is a common electrode for at least four LED chips 12-1 to 12-4 and extends between opposing corners of the housing 16. By way of example, the pin 18-1 is positioned closest to a bottom left corner of the housing 16 while the opposing pin 18-2 of the lead 18 is positioned at a top right corner of the housing 16. In this manner, the lead 18 extends between two corners of the housing 16 that are farthest away from each other. As illustrated, such an arrangement is well suited to position the LED chips 12-1 to 12-4 spaced away from a center point of the housing 16. FIG. 18B is a top view of an LED package 118 that is similar to the LED package 116 of FIG. 18A for embodiments where the LED chips 12-1 to 12-4 embody vertical and/or lateral structures with wire bonds 28.

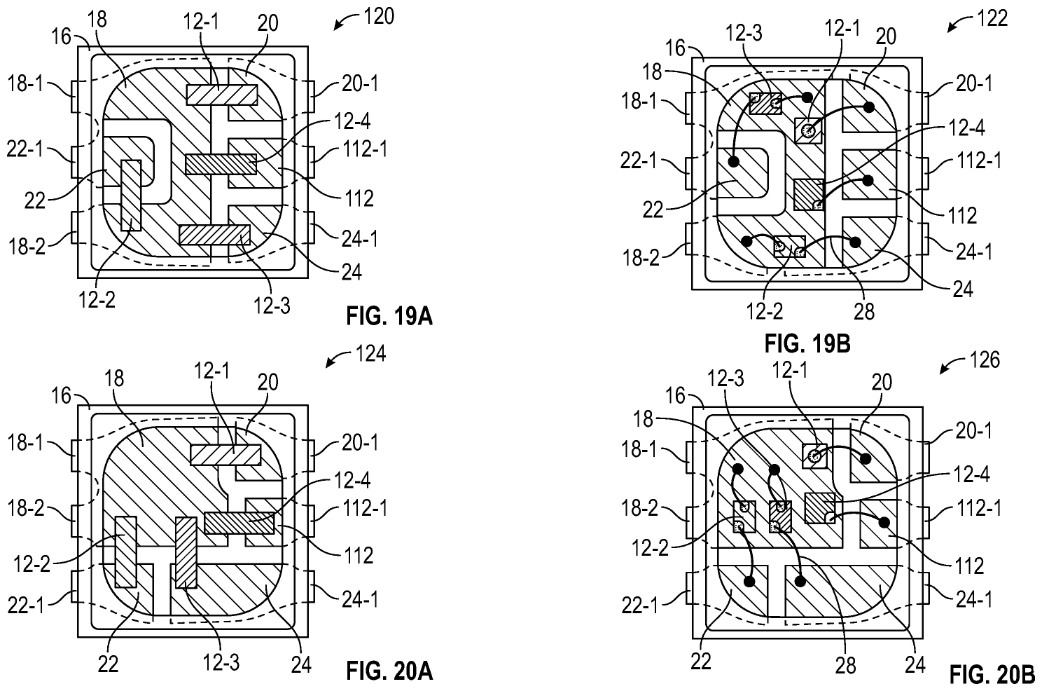

FIG. 19A is a top view of an LED package 120 that is similar to the LED package 110 of FIG. 17A for embodiments where the lead 18 is a common electrode for at least four LED chips 12-1 to 12-4 and extends from one corner of the housing 16 to another corner that is on a same side of the housing 16. As illustrated, the pin 18-1 is positioned closest to the top left corner of the housing 16 while the pin 18-2 is positioned closest to the bottom left corner of the housing 16. The remainder of the lead 18 extends along a center portion of the housing 16, thereby forming a U-shape with the pins 18-1, 18-2 extending from the same side. As further illustrated, the lead 22 and the pin 22-1 may be arranged between portions of the lead 18 that form the U-shape. FIG. 19B is a top view of an LED package 122 that is similar to the LED package 120 of FIG. 19A for embodiments where the LED chips 12-1 to 12-4 embody vertical and/or lateral structures with wire bonds 28.

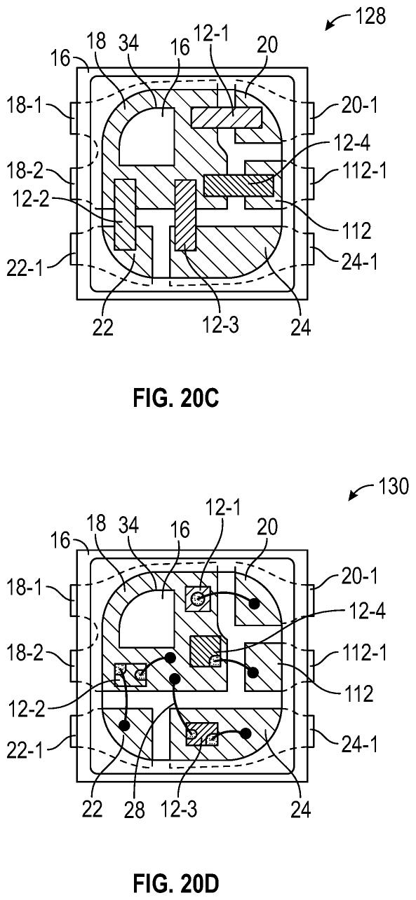

FIG. 20A is a top view of an LED package 124 that is similar to the LED package 120 of FIG. 19A for embodiments where the lead 18 is a common electrode for at least four LED chips 12-1 to 12-4 and the pins 18-1, 18-2 are adjacent to one another on a same side of the housing 16. In this regard, the lead 18 may form a large pad that extends from a corner of the housing 16 toward the center, with the remaining leads 20, 22, 24, 112 positioned proximate a perimeter of the lead 18. The large pad may be beneficial for enhanced heat dissipation. In this arrangement, the pin 22-1 is provided on a same side of the housing 16 as the pins 18-1, 18-2, but not between the pins 18-1, 18-2. FIG. 20B is a top view of an LED package 126 that is similar to the LED package 124 of FIG. 20A for embodiments where the LED chips 12-1 to 12-4 embody vertical and/or lateral structures with wire bonds 28.

FIG. 20C is a top view of an LED package 128 that is similar to the LED package 124 of FIG. 20A for embodiments where the lead 18 includes at least one through-hole 34. FIG. 20D is a top view of an LED package 130 that is similar to the LED package 126 of FIG. 20B for embodiments where the lead 18 includes at least one through-hole 34. As illustrated, the larger pad formed by the lead 18 may also accommodate the through-hole 34 for enhanced adhesion with the housing 16.

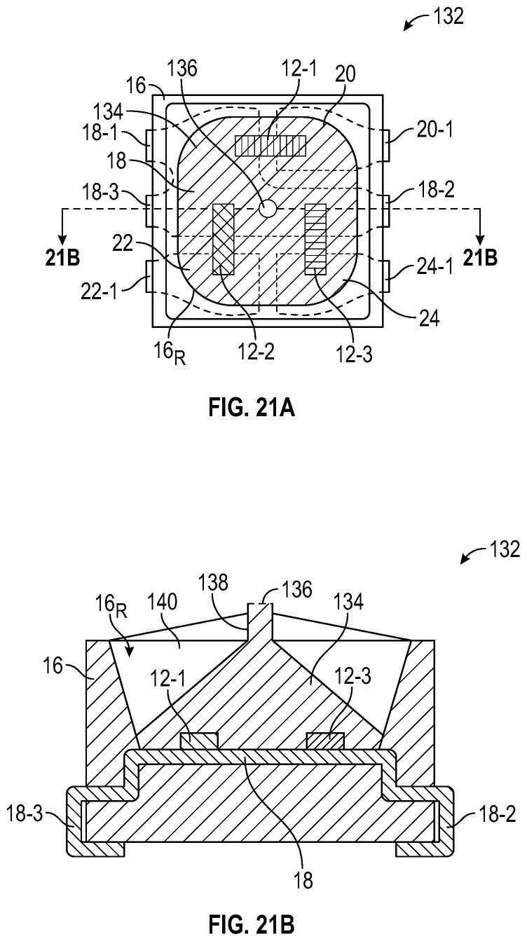

FIG. 21A is a top view of an LED package 132 that is similar to the LED package 82 of FIG. 13A with the addition of a light collector 134. FIG. 21B is a cross-section of the LED package 132 of FIG. 21A taken along the sectional line 21B-21B of FIG. 21A. The light collector 134 is positioned within the recess 16R and over the LED chips 12-1 to 12-3 for collecting light emissions therefrom. In certain embodiments, the light collector 134 includes an aperture 136 and a stem portion 138. The aperture 136 forms a small opening with a size substantially less than a size of the recess 16R that defines an area where light emissions escape the package. In certain embodiments, the light collector 134 may be formed from epoxy, silicone, or some other light-transmissive material. The light collector 134 may be coated with a reflective coating on a top surface thereof except for the aperture 136 at or near the apex, center, or top of the light collector 134. The light collector 134 may comprise a reflective material throughout the light collector 134. For example, the light collector 134 may embody a white material. Light emitted by the LED chips 12-1 to 12-3 enters the light collector 134 and may reflect one or more times, thereby mixing within the light collector 134 before eventually exiting via the aperture 136. The light mixing within the light collector 134 before exiting via the aperture 136 results in light from each of the LED chips 12-1 to 12-3 appearing as if the light originated from a single emission point or area (i.e., the aperture 136) instead of from three separate and distinct locations of the LED chips 12-1 to 12-3. Accordingly, the emission pattern and color over angle shifts of light may be improved. It is to be appreciated that when the present disclosure refers to a single emission point, this is not a point in a mathematical sense, but instead refers to a single emission source (e.g., an LED chip or the output of the plurality of LED chips from the aperture 136). In this sense, a point can be a term for a light source that is smaller than the LED package 132 or system being described, and the size can depend on the overall system.

In certain embodiments, the light collector 134 is configured to receive light from the LED chips 12-1 to 12-3 and the stem portion 138 may have the shape of a cylinder that protrudes from a top, center, or apex of the light collector 134. In other embodiments, the stem portion 138 may have a shape other than being cylindrical. A height of the stem portion 138 can be such that it reduces or avoids a direct line of sight from the LED chips 12-1 to 12-3. In other embodiments, the light collector 134 may be formed without the stem portion 138.

In certain embodiments, a fill material 140 may fill the recess 16R above and around the light collector 134. The aperture 136 may be uncovered by the fill material 140 to allow light to exit the package without interacting with the fill material 140. In various embodiments, the fill material 140 can include light-altering materials, such as light-reflective materials or light-absorptive materials that either entirely or partially reflect or block or reduce light that may pass through or around the light collector 134. In this manner, a majority of the light emitted by the LED package 132 may pass via the aperture 136. The fill material 140 can be an epoxy or silicone that has a composition configured to be light-reflecting or blocking. In certain embodiments, the fill material 140 has a white color for increased reflectivity. In other embodiments, the fill material 140 has a black color for increased contrast of light exiting the LED package 132. In still further embodiments, the fill material 140 may have a white interior color and a black color at a top surface thereof.

As previously described, certain arrangements of the leads 18, 20, 22, 24 are provided so that a layout of the LED chips 12-1 to 12-3 is positioned offset from a center of the housing 16 and/or recess 16R. By way of example, the LED chips 12-1 to 12-3 are shown with a triangular layout within the recess 16R. Such an arrangement may be advantageous for avoiding a direct line of sight for light from any of the LED chips 12-1 to 12-3 through the aperture 136. In still further embodiments, the stem portion 138 may be implemented to further avoid the direct line of sight. In this manner, light from each of the LED chips 12-1 to 12-3 may be positioned radially with respect to the aperture 136 for enhanced light mixing. While the light collector 134 may be useful for such layouts that avoid centrally positioned LED chips 12-1 to 12-3, the light collector 134 may also be implemented in any of the previously described embodiments, including FIGS. 1 to 20D.

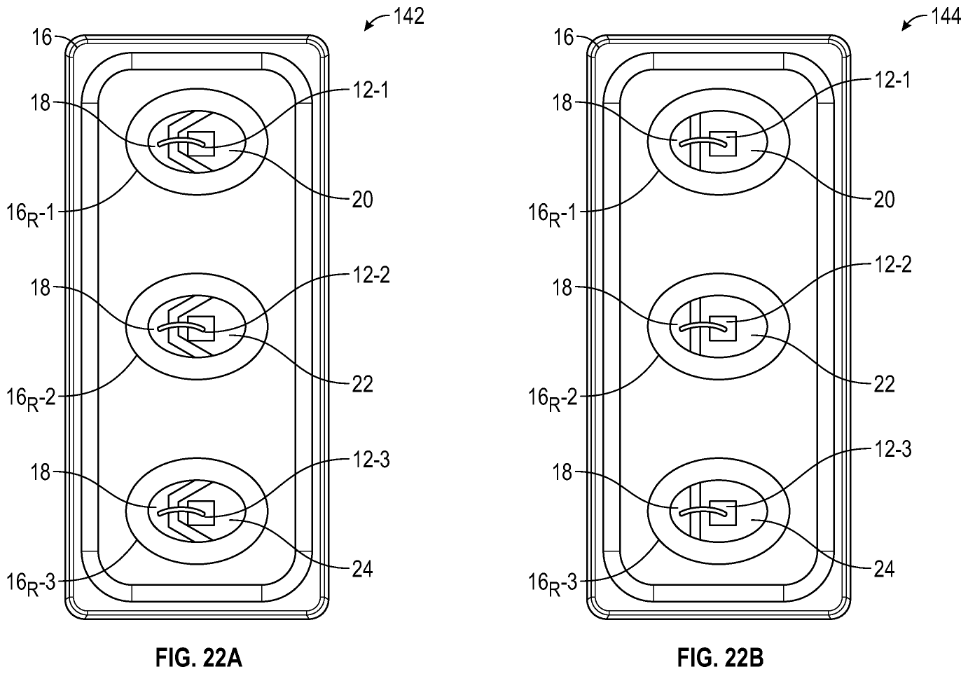

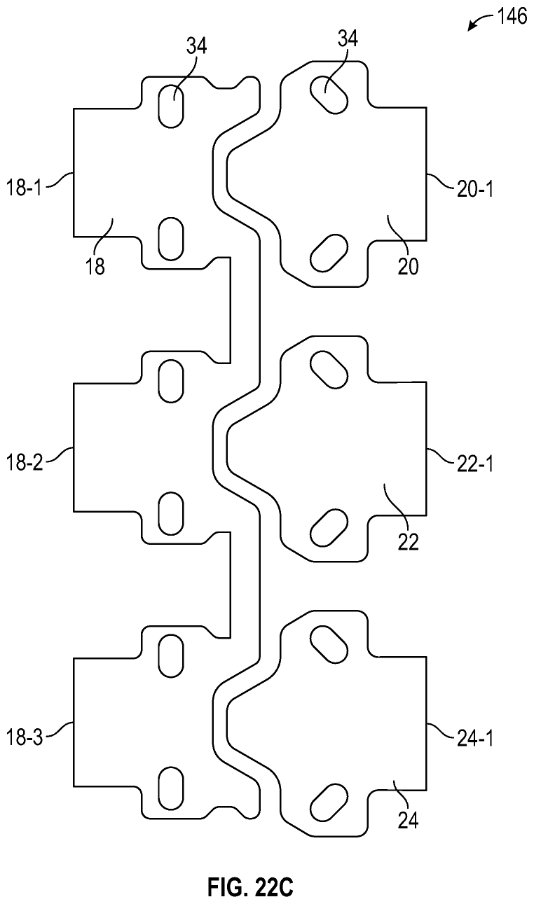

FIG. 22A is a top view of an LED package 142 with multiple cavities or recesses 16R-1 to 16R-3 for the multiple LED chips 12-1 to 12-3 and a common electrode according to principles of the present disclosure. As illustrated, the housing 16 forms multiple recesses 16R-1 to 16R-3, each of which includes one of the LED chips 12-1 to 12-3. The lead 18 forms a common electrode as previously described and extends continuously within the housing 16 to have portions exposed in each of the recesses 16R-1 to 16R-3. The other leads 20, 22, 24 form the other electrodes for each of the LED chips 12-1 to 12-3. In FIG. 22A, the leads 20, 22, 24 have a bump out portion on which each of the LED chips 12-1 to 12-3 resides. As an alternative configuration, FIG. 22B is a top view of an LED package 144 that is similar to the LED package 142 except the leads 20, 22, 24 do not have the bump out portion as illustrated in FIG. 21A.

FIG. 22C is a top view of a lead frame structure 146 that may be implemented in the LED package 142 of FIG. 22A. As illustrated, the lead 18 forms a continuous metal configured to extend between each of the recesses 16R-1 to 16R-3 of FIG. 22A. The leads 20, 22, 24 are discontinuous with each other and discontinuous with the lead 18, thereby forming corresponding electrodes (e.g., anode or cathode) to the common anode or cathode formed by the lead 18. As illustrated, multiple pins 18-1 to 18-3 of the lead 18 are formed and would extend out of a same side of the housing 16 of FIG. 22A. In a similar manner, the pins 20-1, 22-1, 24-1 of the other leads 20-1, 22-1, 24-1 may extend out of the opposite side of the housing 16 of FIG. 22A. In certain embodiments, each of the leads 18, 20, 22, 24 may have one or more through-holes 34 for improved adhesion with the housing 16 of FIG. 22A. In certain embodiments, the lead frame structure 146 may also include one or more indentations and/or the stepped portions, punches, metal gaps, and/or tabs.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a first LED chip;
a second LED chip;
a third LED chip;
a housing; and
a lead frame structure at least partially within the housing and electrically coupled to the first LED chip, the second LED chip, and the third LED chip, the lead frame structure comprising:
a first lead electrically connected to the first LED chip, the second LED chip, and the third LED chip, the first lead comprising multiple pins that extend out of the housing;
a second lead electrically connected to the first LED chip; and
a third lead electrically connected to the second LED chip.

2. The LED package of claim 1, wherein the multiple pins of the first lead extend out of a same side of the housing.

3. The LED package of claim 1, wherein the first lead forms a common anode connection for the first LED chip, the second LED chip, and the third LED chip.

4. The LED package of claim 1, wherein the first lead forms a common cathode connection for the first LED chip, the second LED chip, and the third LED chip.

5. The LED package of claim 1, wherein the first lead extends from a first edge of the housing and past a center line of the housing.

6. The LED package of claim 1, wherein:
a surface of the multiple pins defines a package mounting surface in a first plane;
surfaces of the first lead and second lead define LED chip mounting surfaces in a second plane; and
an intermediate portion of the lead frame structure extends between the first plane and the second plane.

7. The LED package of claim 1, wherein the housing forms a recess in which the first LED chip, the second LED chip, and the third LED chip reside.

8. The LED package of claim 7, further comprising a light collector within the recess and over the first LED chip, the second LED chip, and the third LED chip, the light collector forming an aperture configured to pass light from the first LED chip, the second LED chip, and the third LED chip.

9. The LED package of claim 8, further comprising a fill material within the recess and covering portions of the light collector.

10. The LED package of claim 1, wherein the housing forms a first recess in which the first LED chip resides, a second recess in which the second LED chip resides, and third recess in which the third LED chip resides.

11. The LED package of claim 1, wherein the first LED chip, the second LED chip, and the third LED chip are mounted on and thermally coupled with the first lead.

12. The LED package of claim 1, wherein:
the first LED chip is further mounted on and thermally coupled with the second lead;
the second LED chip is further mounted on and thermally coupled with the third lead; and
the third LED chip is further mounted on and thermally coupled with a fourth lead of the lead frame structure.

13. The LED package of claim 1, further comprising a fourth LED chip, wherein the first lead is a common electrode for the first LED chip, the second LED chip, the third LED chip, and the fourth LED chip.

14. A light-emitting diode (LED) package comprising:
a housing;
a first LED chip;
a second LED chip; and
a lead frame structure with a first lead, the first lead forming a common electrode for the first LED chip and the second LED chip, the first lead comprising multiple pins that extend from a same side of the housing, the multiple pins being configured to receive external electrical connections to the common electrode.

15. The LED package of claim 14, wherein the common electrode is a common anode connection for the first LED chip and the second LED chip.

16. The LED package of claim 14, wherein the common electrode is a common cathode connection for the first LED chip and the second LED chip.

17. The LED package of claim 14, wherein:
a surface of the multiple pins defines a package mounting surface in a first plane;
a surface of the first lead defines an LED chip mounting surface in a second plane; and
an intermediate portion of the lead frame structure extends between the first plane and the second plane.

18. The LED package of claim 14, wherein the housing forms a recess in which the first LED chip and the second LED chip reside.

19. The LED package of claim 18, further comprising a light collector within the recess and over the first LED chip and the second LED chip, the light collector forming an aperture configured to pass light from the first LED chip and the second LED chip.

20. The LED package of claim 19, further comprising a fill material within the recess and covering portions of the light collector.

21. The LED package of claim 14, wherein the housing forms a first recess in which the first LED chip resides and a second recess in which the second LED chip resides.

22. The LED package of claim 14, further comprising a third LED chip, wherein the first lead is the common electrode for the first LED chip, the second LED chip, and the third LED chip.

23. The LED package of claim 14, wherein:
the lead frame structure further comprises a second lead and a third lead;
the first LED chip is flip-chip mounted between the first lead and the second lead; and
the second LED chip is flip-chip mounted between the first lead and the third lead.

24. The LED package of claim 14, wherein the first LED chip and the second LED chip are mounted on and thermally coupled with the first lead.
